(19) United States
(12) Patent Application Publication
(10) Pub. No.: US 2007/0045669 A1
(43) Pub. Date: Mar. 1, 2007

(54) Image sensor

(75) Inventor: Shiro Tsunai, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/488,137

(22) Filed: Jul. 18, 2006

(30) Foreign Application Priority Data
Jul. 19, 2005 (JP) 2005-208165

(51) Int. Cl. H01L 27/148

(52) U.S. Cl. 257/233

(57) ABSTRACT

An image sensor according to an embodiment of the invention includes: a plurality of pixels arranged in line; a reading gate adjacent to the plurality of pixels; a plurality of memory gates formed adjacent to the reading gate and corresponding to the plurality of pixels; a plurality of memory control gates corresponding to the memory gates; and a CCD accumulation gate common to the plurality of memory control gates.

### BACKGROUND OF THE INVENTION

1. Field of the Invention

The present invention relates to an image sensor. In particular, the invention relates to an image sensor capable of outputting data obtained by changing a resolution of a taken image.

2. Description of Related Art

In recent years, CCDs (Charge Coupled Devices) have been widely used as a contact image sensor (CIS) of a scanner. In such devices, the resolution of a taken image is generally changed. The resolution is determined depending on the number of pixels of the CCD. For changing the resolution, there have been adopted a method of processing data retrieved from the CCD and changing the resolution of the data and a method of changing the resolution at the time of retrieving the data from the CCD.

FIG. 16 shows a typical example of conventional CCDs (Related Art 1). The CCD of the Related Art 1 includes plural photodiodes 101 arranged in line, plural CCD accumulation gates 102 for accumulating charges emitted from the plural photodiodes 101, which are arranged in line, barrier gates 103 for preventing leakage of the charges between the CCD accumulation gates 102, and a reading gate 104 as a gate switch between the photodiodes 101 and the accumulation gates 102. Further, the plural accumulation gates 102 and the plural barrier gates 103 constitute a CCD unit 105. The CCD of the Related Art 1 outputs charge information read from the photodiodes 101 from output amplifier 106 through the CCD unit 105. In the CCD unit, the accumulation gates 102 and the barrier gate 103 are paired as a charge transfer element pair. The charge transfer elements are arranged in line. Each charge transfer element is applied with clock pulses φ1 and φ2 that are in opposite phases. Thus, the CCD unit 105 can transmit the charge information from the photodiodes to the output amplifier.

In the CCD of the Related Art 1, however, the photodiodes 101 and the accumulation gates 102 are provided in a one-to-one relation. Hence, the information read by the CCD of the Related Art 1 is determined depending on the number of photodiodes 101 corresponding to the number of pixels. In addition, no more than one resolution type can be obtained from a read image. Thus, in order to obtain images of different resolutions using information read by the CCD of the Related Art 1, the read information needs to be processed. That is, there is a problem in that a given period should be ensured for converting the resolution of the read information in order to obtain plural images of different resolutions.

Japanese Unexamined Patent Application Publication No. 2004-152816 (Related Art 2) discloses an example of a CCD that overcomes the above problem. FIG. 17 shows a CCD of the Related Art 2. As shown in FIG. 17, the CCD of the Related Art 2 includes: a high resolution side CCD unit 111 for obtaining high-resolution information and a high resolution side photodiode line 101A; and a low resolution side CCD unit 112 for obtaining a low-resolution image and a low resolution side photodiode line 101B. In the high resolution side CCD unit 111, one photodiode 101 and one accumulation gate 102 are paired. Further, in the low resolution side CCD unit 112, two photodiodes 101 are connected to one accumulation gate. The high resolution side CCD unit 111 is used for obtaining a high-resolution image, while the low resolution side CCD unit 112 is used for obtaining a low-resolution image. Hence, in the case of generating a low-resolution image, a composite signal of charges of two photodiodes may be read from the low resolution side CCD unit 112. In the case of generating a high-resolution image, charges of the individual photodiodes can be read from the high resolution side CCD unit 111. As a result, only requisite information corresponding to a target resolution can be read. Further, a time period necessary for processing the read information can be shortened. However, the CCD of the Related Art 2 requires plural CCD units and photodiode groups in accordance with resolutions. To that end, pixels are overlapped in a chip, and an area of the CCD unit in the chip increases, resulting in a problem in that the number of effective pixels cannot be increased with respect to a chip area.

Japanese Unexamined Patent Application Publication No. 2001-244448 (Related Art 3) discloses an example of a CCD that overcomes the above problem. FIG. 18 shows the CCD of the Related Art 3. In the CCD of the Related Art 3, a photodiode line 101C having the photodiodes 101 arranged in line is connected with the high resolution side CCD unit 111 and the low resolution side CCD unit 112. Thus, high-resolution information based on charge information from one photodiode 101 and low-resolution information based on a combination of two charge information from the two photodiodes 101 can be separately obtained.

Further, FIG. 19 shows a CCD of the Related Art 4 that is a modified one of the Related Art 3. As shown in FIG. 19, the CCD of the Related Art 4 includes an odd-numbered CCD unit 113 for odd-numbered photodiodes and an even-numbered CCD unit 114 for even-numbered photodiodes as counted from the left side in FIG. 19 in order to read charges from the photodiodes 101 of a photodiode line 101D. Thus, in the case of generating a high-resolution image, charges from the odd-numbered CCD unit 113 and charges from the even-numbered CCD unit 114 are obtained and then, these charges are resorted in the arranging order of photodiodes. In the case of generating a low-resolution image, the image can be obtained by synthesizing charges from the odd-numbered CCD unit 113 and charges from the even-numbered CCD unit 114. That is, an appropriate amount of information can be obtaining in accordance with a resolution of an image.

However, the CCDs of the Related Arts 3 and 4 have a problem in that as many CCD units as resolution types should be prepared, and an area of the CCD units in a chip is also increased, so the number of effective pixels relative to the chip area cannot be increased.

Japanese Unexamined Patent Application Publication No. 2003-332557 (Related Art 5) discloses a technique of extracting a composite charge obtained by synthesizing information of plural pixels corresponding to different color information at one accumulation gate. FIG. 20 shows the CCD of the Related Art 5. As shown in FIG. 20, the CCD of the Related Art 5 includes a CCD unit 105, a reading gate 104A adjacent to the CCD unit 105, memory gates 107 orthogonal to the reading gate 104A, a reading gate 104B adjacent to the memory gates 107, and the photodiodes 101 adjacent to the reading gate 104B. The photodiodes 101 are formed in matrix. The CCD of the Related Art 5 reads information from the photodiode 101 connected to one memory gate 107 from one accumulation gate 102 and outputs the read information.

However, even in the CCD of the Related Art 5, information of the photodiodes connected with adjacent memory gates 107 should be separately read. Thus, in order to reduce information about pixels arranged in a charge transfer direction (main scanning direction) of the CCD unit 105, information output from the output amplifier 106 should be processed. Further, in the case of synthesizing information of pixels arranged in a sub-scanning direction orthogonal to the main scanning direction, only information of the pixels in the sub-scanning direction are reduced, so a pixel ratio between a row direction and a column direction is changed. Thus, even the Related Art 5 cannot reduce the number of pixels at the time of reading a charge from the photodiode. The Related Art 5 finds difficulty in obtaining information corresponding to plural pixels like the Related Art 1.

### SUMMARY OF THE INVENTION

An image sensor according to an aspect of the invention includes: a plurality of pixels arranged in line; a reading gate adjacent to the plurality of pixels; a plurality of memory gates formed adjacent to the reading gate and corresponding to the plurality of pixels; a plurality of memory control gates corresponding to the memory gates; and a CCD accumulation gate common to the plurality of memory control gates.

According to the image sensor of the present invention, one CCD accumulation gate is shared among the plurality of memory control gates, whereby it is possible to reading and synthesizing information about signal charges of plural pixels at the CCD accumulation gate or information about signal charges of the individual pixels can be separately read and transferred.

### BRIEF DESCRIPTION OF THE DRAWINGS

The above and other objects, advantages and features of the present invention will be more apparent from the following description taken in conjunction with the accompanying drawings, in which:

FIG. 1 is a plan view showing a layout of a CCD according to a first embodiment of the present invention;

FIG. 2 is a timing chart of a low-resolution mode operation of the CCD according to the first embodiment;

FIG. 3A is a sectional view of a CCD unit taken along a first direction of the CCD according to the first embodiment;

FIG. 3B shows a potential level upon charge transfer at timing T2 in the sectional view of FIG. 3A;

FIG. 3C shows a potential level upon charge transfer at timing T4 in the sectional view of FIG. 3A;

FIG. 4 is a timing chart of a high-resolution mode operation of the CCD according to the first embodiment;

FIG. 5A is a sectional view of the CCD unit taken along the first direction of the CCD according to the first embodiment;

FIG. 5B shows a potential level upon charge transfer at timing T2 in the sectional view of FIG. 5A;

FIG. 5C shows a potential level upon charge transfer at timing T3 in the sectional view of FIG. 5A;

FIG. 6 is a plan view showing a layout of a CCD according to a second embodiment of the present invention;

FIG. 7 is a timing chart of a low-resolution mode operation of the CCD according to the second embodiment;

FIG. 8 is a plan view showing a layout of a CCD according to a third embodiment of the present invention;

FIG. 9 is a plan view showing a layout of a CCD according to a fourth embodiment of the present invention;

FIG. 10 is a plan view showing a layout of a CCD according to a fifth embodiment of the present invention;

FIG. 11 is a sectional view taken along a direction orthogonal to the first direction of the CCD and a potential level in the sectional view according to the fifth embodiment;

FIG. 12 is a timing chart of a low-resolution mode operation of the CCD according to the fifth embodiment;

FIG. 13 is a timing chart of a high-resolution mode operation of the CCD according to the fifth embodiment;

FIG. 14 is a plan view showing a layout of a CCD according to a sixth embodiment of the present invention;

FIG. 15 is a sectional view taken along a direction orthogonal to the first direction of the CCD and a potential level in the sectional view according to the sixth embodiment;

FIG. 16 is a plan view showing a layout of a CCD of the Related Art 1;

FIG. 17 is a plan view showing a layout of a CCD of the Related Art 2;

FIG. 18 is a plan view showing a layout of a CCD of the Related Art 3;

FIG. 19 is a plan view showing a layout of a CCD of the Related Art 4; and

FIG. 20 is a plan view showing a layout of a CCD of the Related Art 5.

### DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

### First Embodiment

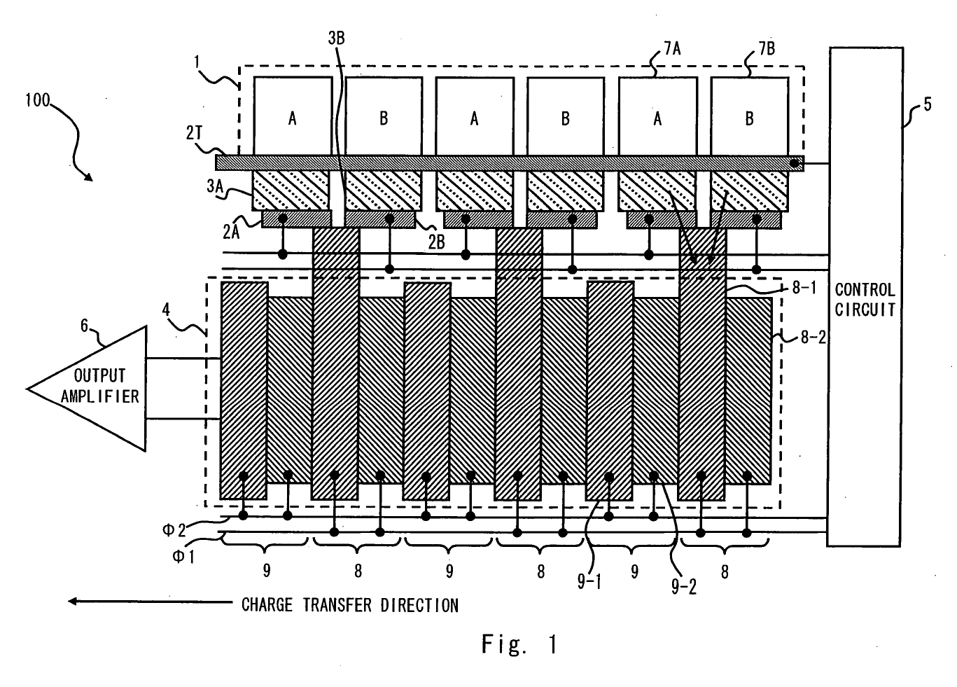

FIG. 1 shows a CCD 100 according to a first embodiment of the present invention. As shown in FIG. 1, the CCD 100 of the first embodiment includes a photodiode line 1, a reading gate 2T, memory control gates 2A and 2B, memory gates 3A and 3B, a CCD unit 4, a control circuit 5, and an output amplifier 6.

The photodiode line 1 has plural photodiodes 7A and 7B arranged in line along a first direction. The photodiodes 7A and 7B generate charges based on incident light. Here, in this embodiment, odd-numbered photodiodes and even-numbered photodiodes as counted from the left side of FIG. 1 are referred to as the photodiodes 7A and the photodiodes 7B, respectively.

The reading gate 2T controls charge transfer between the photodiode line 1 and the memory gates 3. If a high-level voltage (for example, power supply voltage) is applied by the control circuit 5, the reading gate 2T is conductive, and charges are transferred from the photodiode line 1 to the memory gates 3. In contrast, if a low-level voltage (for example, ground voltage) is applied by the control circuit 5,the reading gate 2T is non-conductive, and charge transfer between the photodiode and the memory gates is stopped.

The memory gates 3A and 3B correspond to the photodiodes 7A and 7B, respectively. The gates are elements for temporarily storing charges generated in the photodiodes. The memory gates 3A and 3B are applied with a predetermined level of voltage and accumulate charges.

The memory control gates 2A and 2B control transfer of charges accumulated in the memory gates 3A and 3B to a CCD accumulation gate 8-1, respectively. When a high-level voltage is applied to the memory control gates 2A and 2B, the memory control gates 2A and 2B are conductive, and the charges are transferred from the memory gates 3 to the CCD accumulation gate 8-1. In contrast, when a low-level voltage is applied, the memory control gates 2A and 2B are non-conductive, and no charge is transferred from between the memory gates 3 and the CCD accumulation gate 8-1.

The CCD unit 4 has plural main transfer elements 8 and sub transfer elements 9. The main transfer element 8 is a first charge transfer element and includes the CCD accumulation gate 8-1 and a CCD barrier gate 8-2. The sub transfer element 9 is a second charge transfer element and includes a CCD accumulation gate 9-1 and a CCD barrier gate 9-2. The CCD accumulation gates 8-1 and 9-1 are gates for accumulating charges. The CCD barrier gates 8-2 and 9-2 are gates for generating a potential as a barrier that cuts off the charge transfer between the adjacent CCD accumulation gates 8-1 and 9-1. In addition, the control circuit 5 applies a signal φ1 to the main transfer elements 8, and the control circuit 5 applies a signal φ2 to the sub transfer elements 9.

The control circuit 5 outputs a control signal for the reading gate 2T, the memory control gates 2A and 2B, and the CCD unit 4. These signals are described in more detail below. The output amplifier 6 includes an amplifier, for example, a floating diffusion amplifier having a source-follower circuit, and a charge detector. The output amplifier is a circuit for converting charges from the CCD unit into a signal and outputting the signal to a subsequent circuit.

Here, a charge transfer direction of the CCD unit 4 is defined as a first direction. As shown in FIG. 1, the photodiodes 7A and 7B of the photodiode line 1 are arranged in line along the first direction. These photodiodes are alternately arranged in the order of the photodiodes 7A and 7B as viewed from the left side of FIG. 1.

The reading gate 2T extends in the first direction and is formed in a rectangular shape. One longitudinal side thereof contacts the photodiode line 1, and the other longitudinal side contacts the memory gates 3A and 3B.

The memory gates 3A face the photodiodes 7A across the reading gate 2T. Further, the memory gates 3B face the photodiodes 7B across the reading gate 2T.

The memory control gates 2A and 2B each extend in the first direction and have a rectangular shape. One longitudinal side thereof contacts the memory gates 3A and 3B, and the other longitudinal side contacts the CCD unit 4. The memory control gate 2A is provided to the memory gate 3A on the CCD unit 4 side, and the memory control gate 2B is provided to the memory gate 3B on the CCD unit 4 side. Further, the memory control gates 2A are wired to receive similar control signals. Likewise, the memory control gates 2B are wired to have similar control signals.

In the CCD unit 4, the main transfer elements 8 and the sub transfer elements 9 are alternately arranged in the first direction. In the main transfer element 8, the CCD barrier gate 8-2 and the CCD accumulation gate 8-1 are formed adjacent to each other in this order along the first direction. In the sub transfer element 9, the CCD barrier gate 9-2 and the CCD accumulation gate 9-1 are formed adjacent to each other in this order along the first direction. The CCD accumulation gates 8-1 and 9-1 and the CCD barrier gates 8-2 and 9-2 extend in a direction orthogonal to the first direction and have a rectangular shape. In addition, one widthwise side of the CCD accumulation gate 8-1 contacts the memory control gates 2A and 2B. Further, an output amplifier is formed at an end of the CCD unit 4 in the first direction.

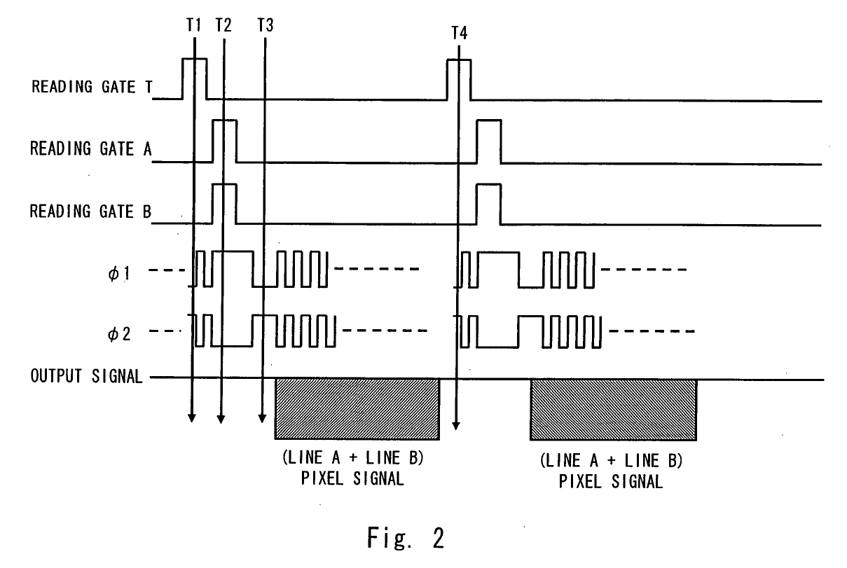

An operation of the CCD 100 of the first embodiment is described in more detail. The CCD 100 of the first embodiment has a first mode for obtaining low-resolution image information (for instance, low-resolution mode) and a second mode for obtaining high-resolution image information (for instance, high-resolution mode). First, a low-resolution mode operation of the CCD 100 is described. FIG. 2 is a timing chart of the low-resolution mode operation of the CCD.

In the CCD 100, the photodiode generates charges in response to the incidence of light. After that, at timing T1, the reading gate 2T is shifted to High level (for instance, power supply voltage level), and the charges generated by the photodiodes 7A and 7B are transferred to the memory gates 3A and 3B.

Then, at timing T2, the memory control gates 2A and 2B are shifted to High level. As a result, the charges accumulated in the memory gates 3A and 3B are transferred to the CCD accumulation gate 8-1 of the main transfer elements and then combined at the CCD accumulation gate 8-1. Subsequently, during a period from timing T3 to timing T4, information about charges accumulated in the CCD accumulation gate 8-1 is output from the output amplifier 6 by way of the CCD unit 4.

In the period from timing T3 to timing T4, charges of all photodiodes are output and from timing T4 onward, the next image information is taken and transferred.

With the above-mentioned operation, the CCD 100 of the first embodiment synthesizes information about charges generated by a line A (photodiodes 7A) and information about charges generated by a line B (photodiodes 7B) with the CCD unit and reads these information at a time.

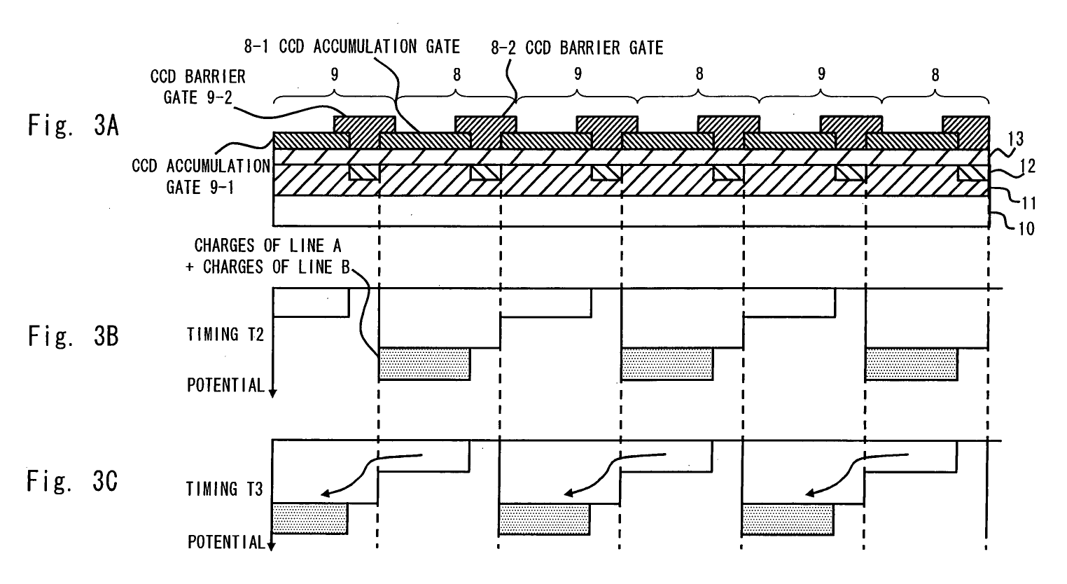

FIG. 3A is a sectional view of the CCD unit 4, and FIGS. 3B and 3C are schematic diagrams of charge transfer of the CCD unit 4 of FIG. 2 at timings T2 and T3. Referring to FIGS. 3A to 3C, the charge transfer operation of the CCD unit 4 is described.

FIG. 3A is a sectional diagram of the CCD unit 4 taken along the first direction. As viewed in section of the CCD unit 4, an N-type diffusion layer 11 is formed on a P-type semiconductor substrate 10, and an N-type diffusion layer 12 is selectively formed on the N-type diffusion layer. An oxide film layer 13 is formed to cover the surfaces of the N-type diffusion layer 11 and the N-type diffusion layer 12. The polysilicon-made CCD accumulation gates 8-1 and 9-1 are formed as electrodes on the surface of the oxide film layer 13 and above a region where the N-type diffusion layer 11 contacts the oxide film layer 13. Further, the polysilicon-made CCD barrier gates 8-2 and 9-2 are formed as electrodes on the surface of the oxide film layer 13 and above a region where the N-type diffusion layer 12 contacts the oxide film layer 13.

FIG. 3B is a schematic diagram of a potential of the CCD unit 4 and accumulated charges at timing T2. At timing T2, the main transfer elements 8 are applied with a high-level voltage (signal φ1), while the sub transfer elements 9 are applied with a low-level voltage (signal φ2 ). Thus, a potential is lowered in the order of the CCD barrier gate 9-2, the CCD accumulation gate 9-1, the CCD barrier gate 8-2, and the CCD accumulation gate 8-1.

The CCD accumulation gate 8-1 of the main transfer element 8 is adjacent to the memory control gates 2A and 2B. At timing T2, the memory control gates 2A and 2B is applied with a high-level voltage and to be conductive. Thus, the CCD accumulation gate 8-1 of the lowest potential accumulates the total amount of charges of the photodiodes 7A and 7B.

FIG. 3C is a schematic diagram of a potential of the CCD unit 4 and accumulated charges at timing T3. At timing T3, the main transfer elements 8 are applied with a low-level voltage (signal φ1), while the sub transfer elements 9 are applied with a high-level voltage (signal φ2 ). Accordingly, a potential of each gate is lowered in the order of the CCD barrier gate 8-2, the CCD accumulation gate 8-1, the CCD barrier gate 9-2, and the CCD accumulation gate 9-1.

The charges accumulated in the CCD accumulation gate 8-1 of the lowest potential at timing T2 are accumulated in the CCD accumulation gate 9-1 at timing T3. That is, the charges accumulated in the CCD accumulation gate 8-1 are transferred to the CCD accumulation gate 9-1 of the lower potential at timing T3. During a period from timing T3 to timing T4, the signals φ1 and φ2 are clock pulses in opposite phases. Accordingly, charges of the CCD accumulation gates 8-1 and 9-1 are moved in response to the signals φ1 and φ2 so as to establish connection with the output amplifier 6.

Here, the CCD barrier gates 8-2 and 9-2 always have a potential higher than that of the CCD accumulation gate. Accordingly, even through the potential of the CCD accumulation gate is changed, charges are never moved in the direction blocked by the CCD barrier gate.

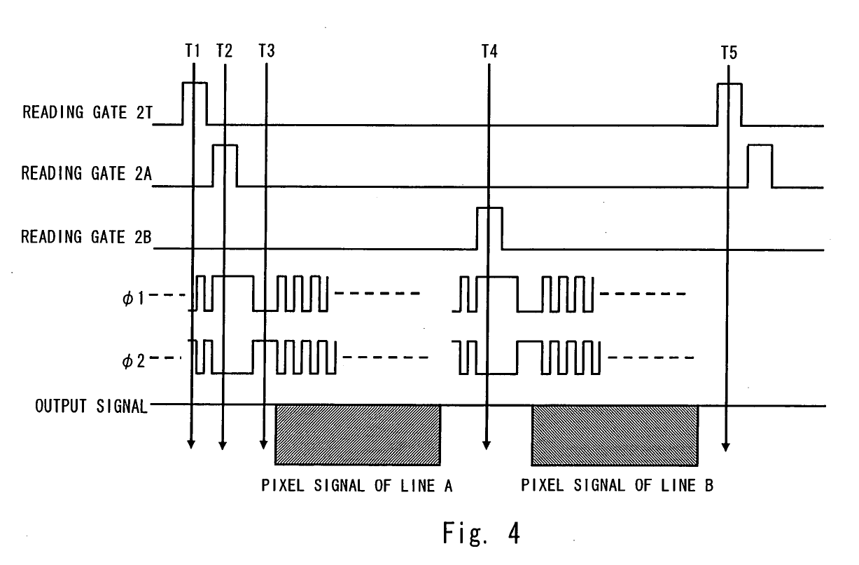

Next, the high-resolution mode operation of the CCD is described. FIG. 4 is a timing chart of a high-resolution mode operation of the CCD 100.

As shown in FIG. 4, in the high-resolution mode, the reading gate 2T, and the signals φ1 and φ2 are at substantially the same level as that in the low-resolution mode. In the low-resolution mode, the memory control gates 2A and 2B are shifted to High level at the same timing, while in the high-resolution mode, the memory control gates 2A and 2B are shifted to High level at different timings.

That is, in the high-resolution mode, the memory control gates 2A and 2B are separately shifted to High level at timings T2 and T4. Thus, the CCD unit 4 first transfers charges generated by the photodiode 7A and then transfers charges generated by the photodiode 7B.

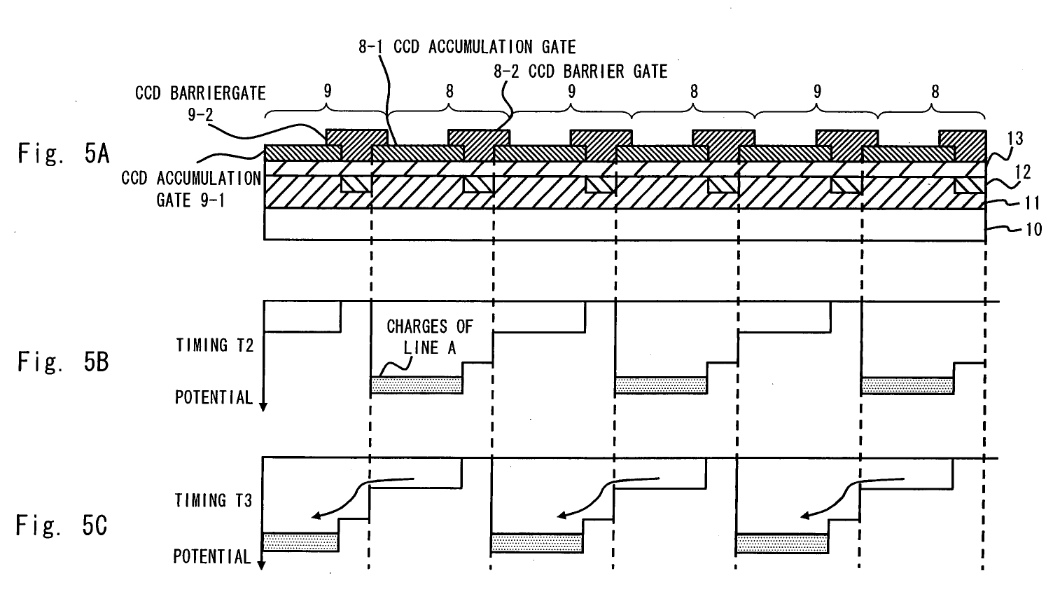

FIG. 5A is a sectional view of the CCD unit 4 in the high-resolution mode, and FIGS. 5B and 5C are schematic diagrams of charge transfer of the CCD unit 4 at timings T2 and T3 of FIG. 4. As shown in FIGS. 5A to 5C, in the low-resolution mode, the CCD accumulation gate 8-1 accumulates charges generated by the photodiode 7A at timing T2 (FIG. 5B). The charges are transferred to the CCD accumulation gate 9-1 of the sub transfer elements 9 at timing T3 (FIG. 5C). Incidentally, in the high-resolution mode, the charges of all the photodiodes are concurrently read and stored in the memory gates in order to prevent deterioration of a resolution in a sub-scanning direction due to an operation of reading information about charges of the photodiodes in two stages.

As described above, according to the CCD 100 of the first embodiment, the memory control gates 2A and 2B are brought into conduction at a timing in the case of forming a low-resolution image, whereby the charges of two photodiodes are combined and read at the CCD accumulation gate 8-1. That is, since charges can be combined at the CCD accumulation gate and read as single information, on the assumption that the total number of pixels is n, the number of reading pixels is n/2. In other words, in the low-resolution mode, a period necessary for reading pixel information can be reduced to about ½ of that in the high-resolution mode.

Further, in the case of forming a high-resolution image, the memory control gates 2A and 2B are separately brought into conduction, so information corresponding to individual pixels can be separately taken. In this case, the number of reading pixels is n. Even in the case of reading a high-resolution image, a reading speed is equivalent to that of a conventional CCD.

According to the CCD 100 of the first embodiment, even in such a structure that one CCD unit is provided for pixels arranged in line, the memory control gates 2A and 2B are controlled, so it is possible to determine whether information corresponding to each pixel are individually take or combined and taken. Thus, it is unnecessary to provide any redundant elements in a chip, so a ratio of effective pixels to the total chip area can be increased.

### Second Embodiment

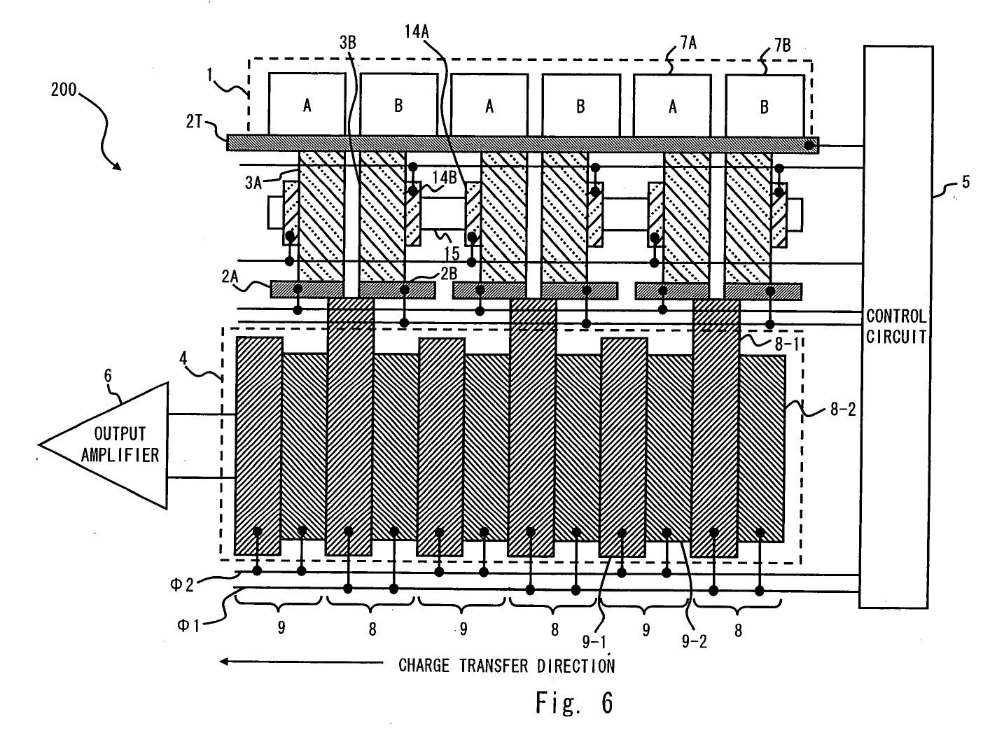

FIG. 6 shows a CCD 200 according to a second embodiment of the present invention. The CCD 200 of the second embodiment is substantially the same as the CCD 100 of the first embodiment. The CCD of the second embodiment includes, in addition to the components of the CCD 100 of the first embodiment, reset gates 14A and 14B formed adjacent to the memory gates 3, and a reset drain 15 formed adjacent to the reset gates 14A and 14B. The same components as those of the first embodiment are denoted by identical reference numerals and their description is omitted here.

The reset gates 14A and 14B are formed adjacent to the memory gates 3A and 3B, respectively. In the case where the reset gates 14A and 14B are applied with a high-level voltage, the memory gates 3A and 3B and the reset drain 15 are brought into conduction. IN the case where the reset gates 14A and 14B are applied with a low-level voltage, the memory gates 3A and 3B and the reset drain 15 are not brought into conduction.

The reset drain 15 is formed adjacent to the reset gates 14A and 14B. The reset drain 15 is used for outputting charges accumulated in the memory gates 3A and 3B.

The detailed operation of the CCD 200 of the second embodiment is described. The CCD 200 of the second embodiment operates similarly to the first embodiment if the reset gate is not used (reset gate is at low level). In the case of using charges of one of the photodiodes 7A and 7B, the CCD 200 of the second embodiment transfers charges of the other photodiode to the reset drain 15.

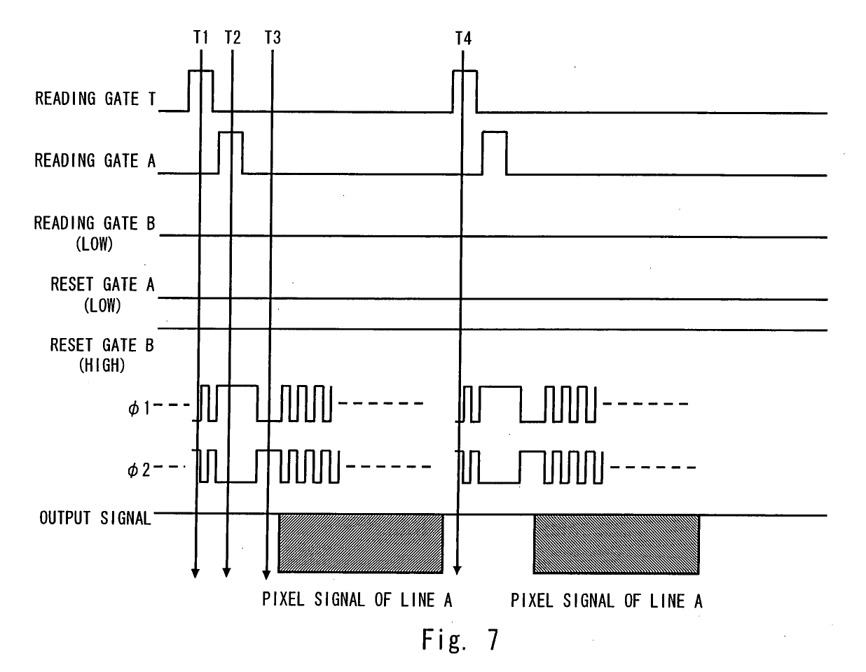

FIG. 7 is a timing chart of an operation of the CCD 200 of the second embodiment in the case of using only the photodiode 7A out of the two photodiodes.

As shown in FIG. 7, if charges of the photodiode 7B are not used, the rest gate of the photodiode 7B is kept at High level. In addition, the memory control gate 2B is kept at Low level without applying a pulse.

The reading gate 2T is shifted to High level at timing T1. At this time, charges are transferred from the photodiodes 7A and 7B to the memory gates 3A and 3B. Here, since the reset gate 14B is at High level, charges of the memory gates 3B are output to the reset drain 15. Further, the reset drain 15 is applied with a low-level voltage, so the charges are accumulated in the memory gates 3A.

When the memory control gate 2A is shifted to High level at timing T2, the charges accumulated in the memory gate 3A are transferred to the CCD accumulation gate 8-1. In the CCD unit 4, the transfer of these charges is started at timing T3 and the charges are output through an output amplifier. Further, from timing T4 onward, charges generated by the photodiode 7A are read and transferred as in a period from timing T1 to timing T4.

According to the CCD of the second embodiment, the reset gates and the reset drain are provided adjacent to the memory gate, whereby unnecessary charges can be output to the outside of the CCD. Thus, it is possible to avoid such a situation that unnecessary charges generated by the photodiode are continuously accumulated and the photodiode and the memory gate are saturated. In addition, in the case of synthesizing information of two pixels for obtaining low-resolution image information, an amount of combined charges is too large and the CCD accumulation gate is saturated in some cases. In the second embodiment, however, only information of one of the two pixels is used, making it possible to prevent saturation of the CCD accumulation gate.

### Third Embodiment

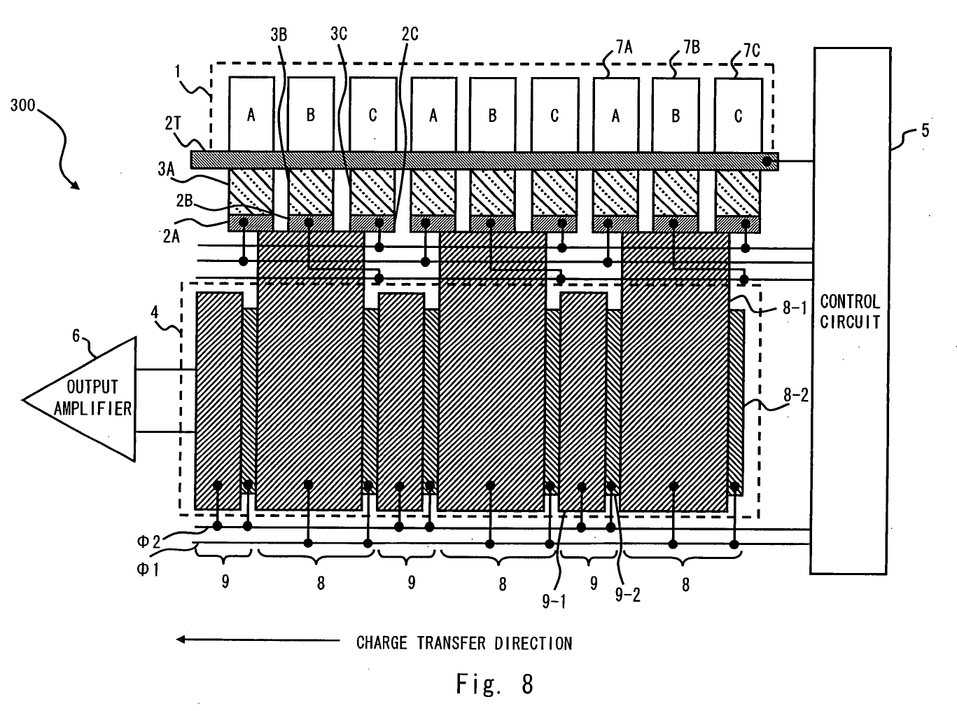

FIG. 8 shows a CCD 300 according to a third embodiment of the present invention. The CCD 300 of the third embodiment is substantially the same as the CCD 100 of the first embodiment. In the CCD 100 of the first embodiment, two photodiodes are operated in pair. In contrast, in the CCD 300 of the third embodiment, a set of three photodiodes is operated. The same components as those of the first embodiment are denoted by identical reference numerals and their description is omitted here.

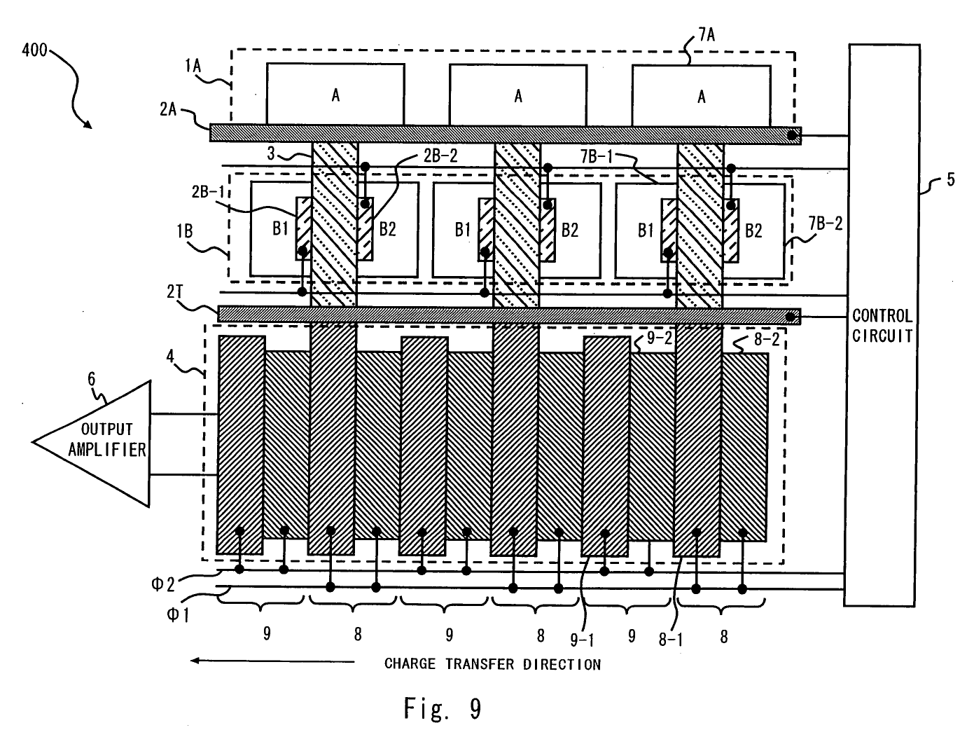

Referring to FIG. 8, the layout of the CCD 300 of the third embodiment is described in detail. Here, a charge transfer direction of the CCD unit 4 is assumed as a first direction. As shown in FIG. 9, photodiodes 7A, 7B, and 7C of the photodiode line 1 are arranged in line along the first direction. The photodiodes 7A, 7B, and 7C are alternately arranged in this order as viewed from the left side of FIG. 9.

The reading gate 2T extends in the first direction and has a rectangular shape. One longitudinal side of the gat contacts the photodiode line 1, and the other longitudinal side contacts the memory gates 3A, 3B, and 3C.

The memory gates 3A face the photodiodes 7A across the reading gate 2T, and the side of each gate on the photodiode 7A side contacts the reading gate 2T. The memory gates 3B face the photodiodes 7B across the reading gate 2T, and the side of each gate on the photodiode 7B side contacts the reading gate 2T. The memory gates 3C face the photodiodes 7C across the reading gate 2T, and the side of each gate on the photodiode 7C side contacts the reading gate 2T.

The memory control gates 2A, 2B, and 2C extend in the first direction and have a rectangular shape. One longitudinal side of the gate contacts the memory gate, and the other longitudinal side contacts the CCD unit 4. The memory control gate 2A is provided to the memory gate 3A on the CCD unit 4 side. The memory control gate 2B is provided to the memory gate 3B on the CCD unit 4 side. The memory control gate 2C is provided to the memory gate 3C on the CCD unit 4 side.

In the CCD unit 4, the main transfer elements 8 and the sub transfer elements 9 are alternately provided adjacent to each other in the first direction. In the main transfer elements 8, the CCD barrier gate 8-2 and the CCD accumulation gate 8-1 are formed adjacent to each other in the first direction in this order. In the sub transfer elements 9, the CCD barrier gate 9-2 and the CCD accumulation gate 9-1 are formed in the first direction in this order. The CCD accumulation gates 8-1 and 9-1 and the CCD barrier gates 8-2 and 9-2 extend orthogonally to the first direction and have a rectangular shape. Further, one widthwise side of the CCD accumulation gate 8-1 contacts the memory control gates 2A, 2B, and 2C. Furthermore, an output amplifier is formed at an end of the CCD unit 4 in the first direction.

In the CCD 300 of the third embodiment, in the case of reading information about charges stored in the memory gate, the memory control gates 2A, 2B, and 2C are concurrently brought into conduction, so charges of three pixels are combined into single information and the information can be read. Further, the memory control gates 2A, 2B, and 2C are brought into conduction at different timings, so information about each pixel can be separately obtained. Further, for example, the memory control gates 2A and 2B are concurrently brought into conduction, and the memory control gate 2C is brought into conduction at another timing, whereby synthesized information about two pixels among the three pixels and information about the remaining one pixel can be separately obtained. That is, the CCD 300 of the third embodiment enables three modes: a first mode for obtaining one information as synthesized information about three pixels (for instance, low-resolution mode); a third mode for separately obtaining synthesized information of two pixels and information of the remaining one pixel (for instance, intermediate-resolution mode); and a second mode for separately obtaining information of each pixel (for instance, high-resolution mode).

Incidentally, in order to prevent saturation due to an excessive amount of charges at the memory gate, the reset gate and the reset drain may be formed adjacent to the memory gate. Further, in order to prevent a photodiode from being saturated with an excessive amount of charges, a shutter gate or an overflow drain may be provided adjacent to the gate.

### Fourth Embodiment

FIG. 9 shows a CCD 400 according to a fourth embodiment of the present invention. In the CCD 400 of the fourth embodiment, the memory gate combines charges of photodiodes every three of which are brought together into one group and the charges are transferred to the CCD unit.

Referring to FIG. 9, the layout of the CCD 400 of the fourth embodiment is described. Here, a charge transfer direction of the CCD unit 4 is assumed as the first direction. Further, in this embodiment, there are two photodiode lines that are set as photodiodes lines 1A and 1B. The photodiodes of the photodiode line 1A are assumed as first pixels (for instance, photodiodes 7A), and the photodiodes of the photodiode line 1B are assumed as second pixels (for instance, photodiodes 7B-1 and 7B-2).

As shown in FIG. 9, the photodiodes 7A of the photodiode line 1A are arranged in line along the first direction. A first reading gate (for instance, memory control gate 2A) extends in the first direction and has a rectangular shape. One longitudinal side of the gate contacts the photodiode line 1A, and the other longitudinal side of the gate contacts the memory gate 3.

The memory gate 3 faces the photodiode 7A across the memory control gate 2A, and one side of the gate that opposes the photodiode 7A contacts a third reading gate (for instance, reading gate 2T). Further, a second reading gate (for instance, memory control gate 2B-1) contacts one side of the memory gate 3 that extends in a second direction orthogonal to the first direction, and the second reading gate (for instance, memory control gate 2B-2) contacts the other side. Further, a photodiode 7B-1 having a size different from the photodiode 7A is formed adjacent to the memory control gate 2B-1, and a photodiode 7B-2 having a size different from the photodiode 7A is formed adjacent to the memory control gate 2B-2.

The reading gate 2T extends in the first direction and has a rectangular shape. One longitudinal side of the gate contacts the memory gate 3, and the other longitudinal side contacts the CCD accumulation gate 8-1 of the CCD unit 4.

In the CCD unit 4, the main transfer elements 8 and the sub transfer elements 9 are alternately arranged adjacent to each other in the first direction. In the main transfer elements 8, the CCD barrier gate 8-2 and the CCD accumulation gate 8-1 are formed adjacent to each other in the first direction in this order. In the sub transfer elements 9, the CCD barrier gate 9-2 and the CCD accumulation gate 9-1 are formed in the first direction in this order. The CCD accumulation gates 8-1 and 9-1 and the CCD barrier gates 8-2 and 9-2 extend orthogonally to the first direction and have a rectangular shape. In addition, one widthwise side of the CCD accumulation gate 8-1 contacts the reading gate 2T. Further, an output amplifier is formed at an end of the CCD unit 4 in the first direction.

According to the CCD 400 of the fourth embodiment, three photodiodes of different sizes are connected to one memory gate, so high-resolution information using the photodiodes A, B1 and B2, and intermediate-resolution information and low-resolution information based on a combination of the photodiodes A, B1 and B2 can be obtained. In addition, according to the CCD 400 of the fourth embodiment, it is unnecessary to provide a CCD for charge transfer between photodiodes unlike the Related Art 3. Thus, as compared with the Related Art 3, a distance between the photodiode line and the CCD unit orthogonal to the first direction can be reduced. Hence, a line interval, which influences a finished quality of an image formed by synthesizing signals after reading signal charges and reconstructing the original image, can be reduced.

Although not shown, photodiodes may be provided with a shutter gate and an overflow drain for preventing a saturation state due to an excessive amount of charges when not in use. Alternatively, a rest gate and a reset drain may be provided to the memory gate.

### Fifth Embodiment

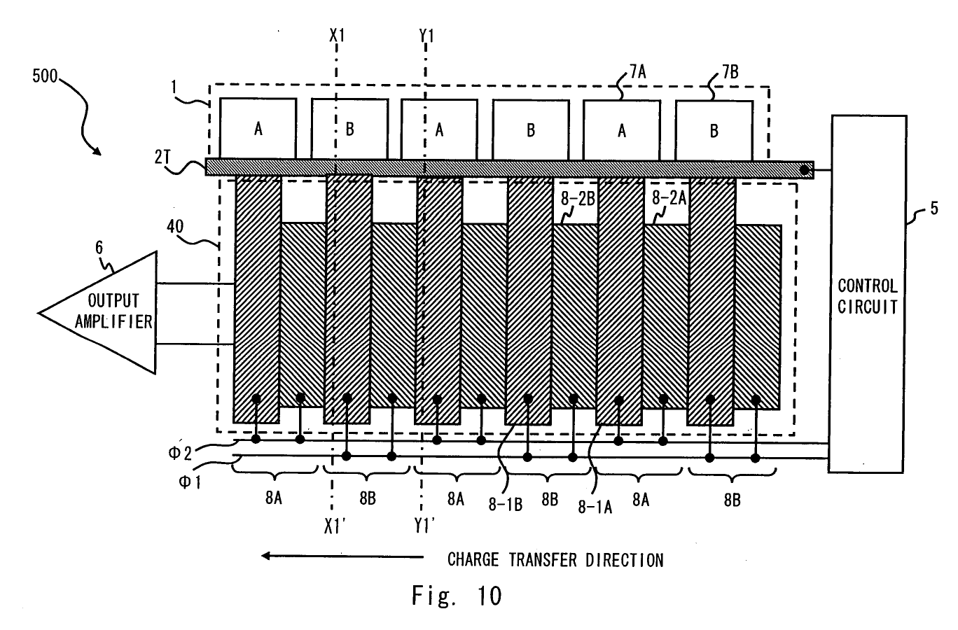

FIG. 10 shows a CCD 500 according to a fifth embodiment of the present invention. The structure of the CCD 100 of the first embodiment is simplified by omitting the memory gates 3 and the memory control gates 2A and 2B. Further, the signals φ1 and φ2 for controlling the CCD unit 40 are changed to thereby read high-resolution information and low-resolution information using one photodiode line and one CCD unit. Further, the CCD unit 40 of the fifth embodiment has the arranged main transfer elements 8 and does not have the sub transfer elements 9.

Referring to FIG. 10, the layout of the CCD 500 of the fifth embodiment is described in detail. Here, the charge transfer direction of the CCD unit 40 is referred to as the first direction. As shown in FIG. 10, the photodiodes 7A and 7B of the photodiode line 1 are arranged in line along the first direction. The photodiodes 7A and 7B are alternately arranged in this order as viewed from the left side of FIG. 10.

The reading gate 2T extends in the first direction and has a rectangular shape. One longitudinal side of the gate contacts the gate, and the other longitudinal side contacts the CCD accumulation gate 8-1 of the CCD unit 4.

In the CCD unit 4, the main transfer elements 8A corresponding to the photodiodes 7A and the main transfer elements 8B corresponding to the photodiodes 7B are alternately arranged adjacent to each other in the first direction. In the main transfer elements 8A, the CCD barrier gate 8-2A and the CCD accumulation gate 8-1A are arranged in this order along the first direction. In the main transfer elements 8B, the CCD barrier gate 8-2B and the CCD accumulation gate 8-1B are arranged adjacent to each other in this order along the first direction. The CCD accumulation gates 8-1A and 8-1B, and the CCD barrier gates 8-2A and 8-2B extend orthogonally to the first direction and have a rectangular shape. Further, one widthwise side of the CCD accumulation gates 8-1A and 8-1B contacts the reading gate 2T. In addition, the main transfer elements 8A are driven with the signal φ2, and the main transfer elements 8B are driven with the signal φ1 . Furthermore, an output amplifier is formed at an end of the CCD unit 4 in the first direction.

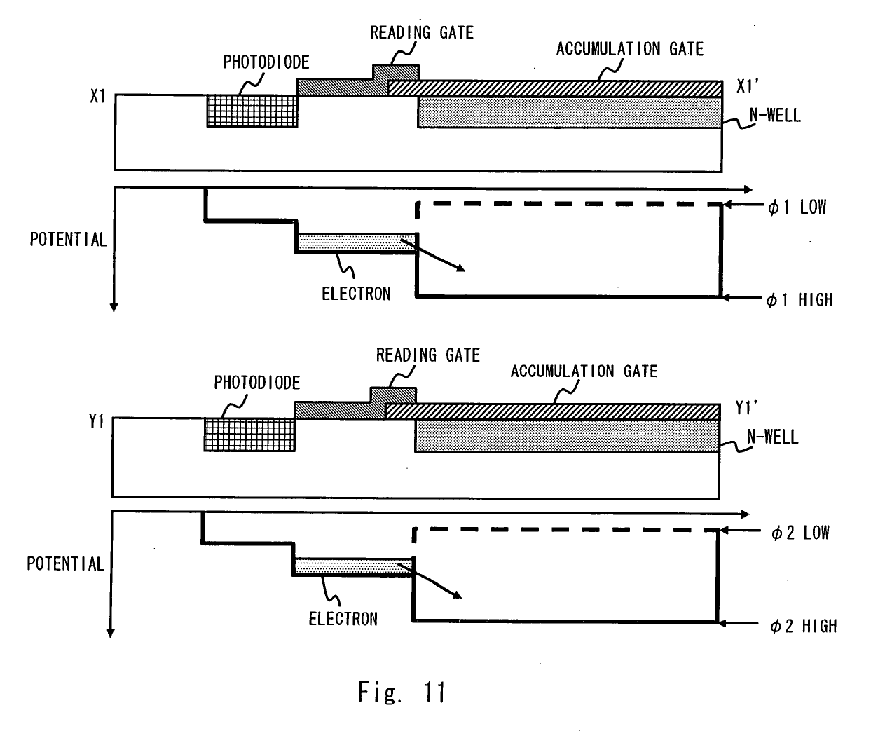

FIG. 11A is a schematic diagram of the section of CCD 500 taken along the line X1-X1′ of FIG. 10 and a potential change. As shown in FIG. 11A, a reading gate is applied with a high-level voltage, and the signal φ1 is at High level, a potential is lowered in the order of the photodiodes, the reading gate, and the CCD accumulation gate. Accordingly, in such a case, charges generated by the photodiode are moved to the CCD accumulation gate of the lowest potential. Further, if the signal φ1 is at Low level, a potential of the CCD accumulation gate becomes higher (potential as indicated by the broken line of FIG. 11A), and no charges are moved to the CCD accumulation gate.

FIG. 11B is a schematic diagram of the section of CCD 500 taken along the line Y1-Y1′ of FIG. 10 and a potential change. Even in FIG. 11B, the same potential change as that of FIG. 11A is achieved except that the control signal φ2 replaces the control signal φ1 .

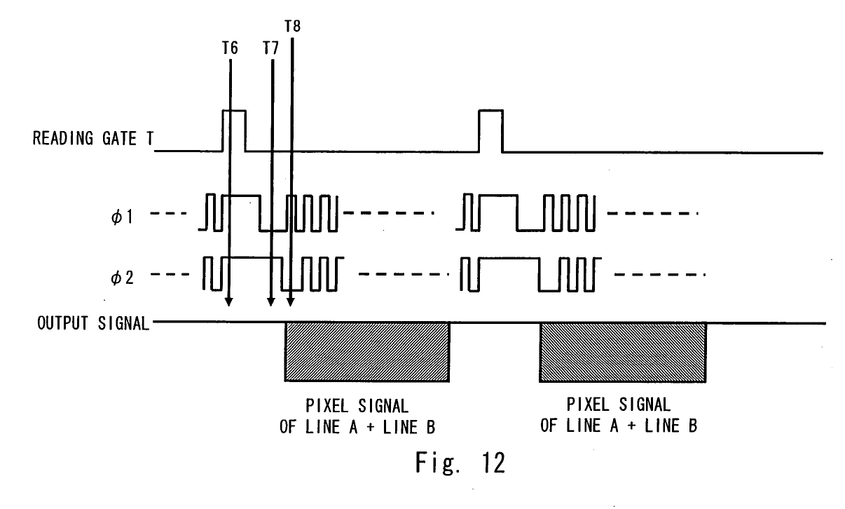

An operation of the CCD 500 of the fifth embodiment is described. FIG. 12 is a timing chart of a low-resolution mode operation of the CCD of the fifth embodiment. Referring to FIG. 12, the low-resolution mode operation of the CCD 500 of the fifth embodiment is described.

First, at timing T6, the reading gate 2T, and the signals φ1 and φ2 are shifted to High level, whereby charges of the photodiodes 7A and 7B are moved to the CCD accumulation gates 8-1A and 8-1B. Next, at timing T7, the reading gate 2T and the signal φ1 are shifted to Low level. At this time, the signal φ2 is kept at High level. In response to the signal φ1 , the potential of the CCD accumulation gate 8-1B applied with the signal φ1 is increased. Hence, charges accumulated in the CCD accumulation gate 8-1B are transferred to the CCD accumulation gate 8-1A, and the CCD accumulation gate 8-1A accumulates the sum of charges generated by the photodiodes 7A and 7B.

At timing T8, the signal φ1 is shifted to High level, and the signal φ2 is shifted to Low level. Accordingly, charges accumulated in the CCD accumulation gate 8-1A are transferred to the CCD accumulation gate 8-1B. After that, charges are transferred to an output amplifier using the signals φ1 and φ2 in opposite phases.

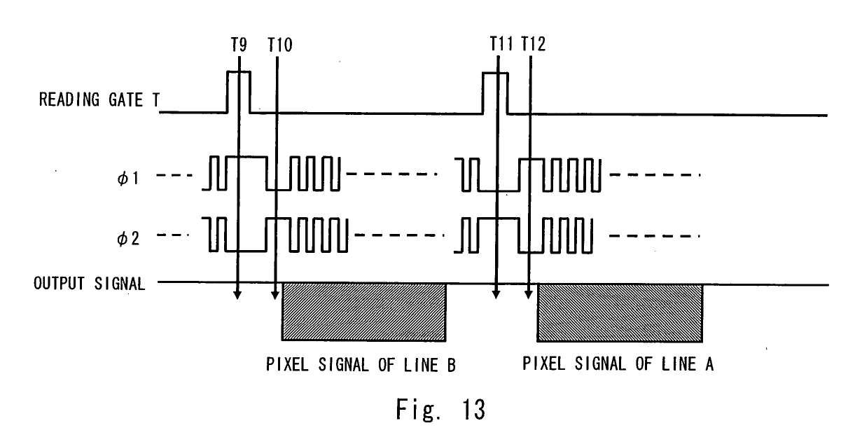

Next, a high-resolution mode operation is described. FIG. 13 is a timing chart of the high-resolution mode operation. Referring to FIG. 13, the high-resolution mode operation of the CCD 500 of the fifth embodiment is described.

First, at timing T9, the reading gate 2T and the signal φ1 are shifted to High level, and the signal φ2 is shifted to Low level. Thus, charges generated by the photodiode 7B are accumulated in the CCD accumulation gate 8-1B. At timing T10, the reading gate 2T and the signal φ1 are shifted to Low level, and the signal φ2 is shifted to High level, whereby the accumulated charges are transferred from the CCD accumulation gate 8-1B to the CCD accumulation gate 8-1A. After that, until timing T11, the charges generated by the photodiode 7B are transferred to the output amplifier.

Next, at timing T11, the reading gate 2T and the signal φ2 are shifted to High level, and the signal φ1 is shifted to Low level. Thus, charges generated by the photodiode 7A are accumulated in the CCD accumulation gate 8-1A. At timing T12, the reading gate 2T and the signal φ2 are shifted to Low level, and the signal φ1 is shifted to High level, so the accumulated charges are transferred from the CCD accumulation gate 8-1A to the CCD accumulation gate 8-1B. After that, charges generated by the photodiode 7A are transferred to the output amplifier.

According to the CCD 500 of the fifth embodiment, information necessary for obtaining a low-resolution image can be obtained in a period shorter than that in the case of obtaining a low-resolution image even with the structure simpler than that of the first embodiment. That is, in the low-resolution mode, information about charges of all pixels are read at a time, after which charges of the two pixels are combined and transferred to thereby obtain information. On the other hand, in the high-resolution mode, charges of adjacent pixels are read at different timings and transferred. Thus, the high-resolution information can be obtained.

### Sixth Embodiment

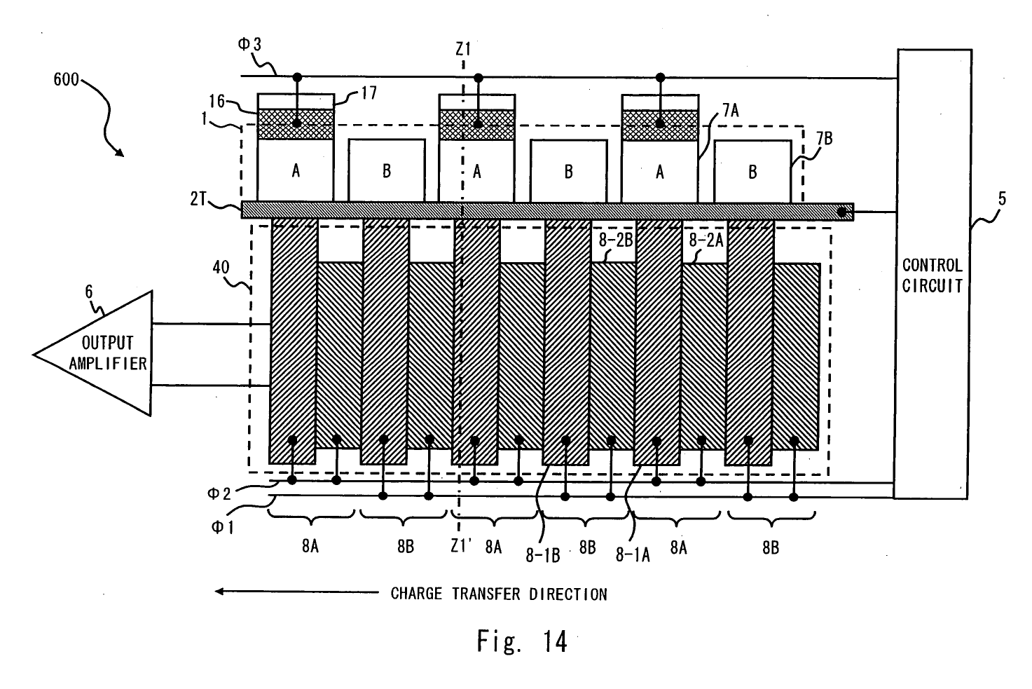

FIG. 14 shows a CCD 600 according to a sixth embodiment of the present invention. As compared with the CCD 500 of the fifth embodiment, in the CCD 600 of the sixth embodiment, the photodiode A is provided with a shutter gate 16 controlled by a signal φ3 and a reset drain 17 as a charge output portion, which are formed adjacent to each other. The CCD 600 of the sixth embodiment operates in substantially the same manner as that of the CCD 500 of the fifth embodiment in the high-resolution mode. Further, in the low-resolution mode, the CCD 500 of the fifth embodiment combines charges generated by the photodiodes 7A and 7B, while the CCD 600 of the sixth embodiment reads only information about charges from the photodiode 7B, and the charges of the photodiode 7A are output to the reset drain 17 through the shutter gate 16.

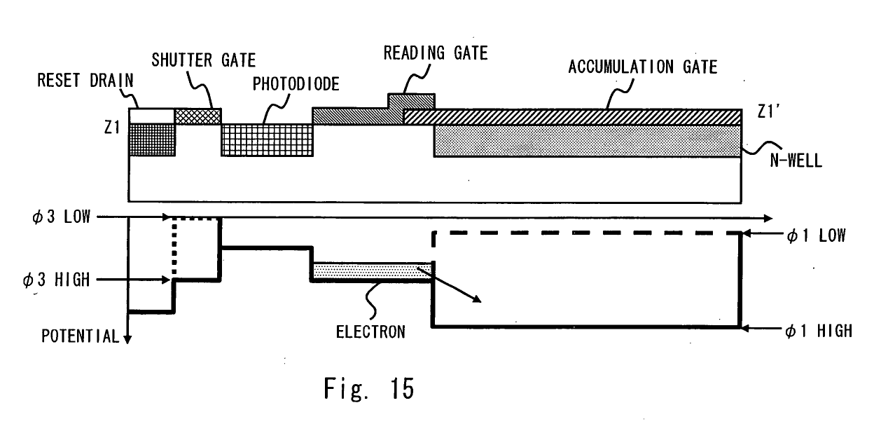

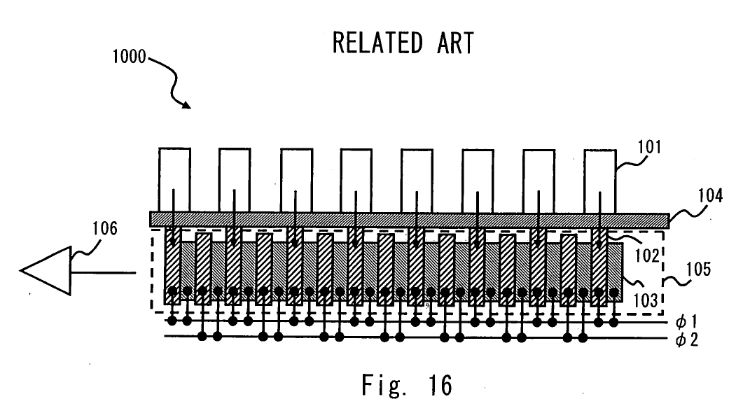

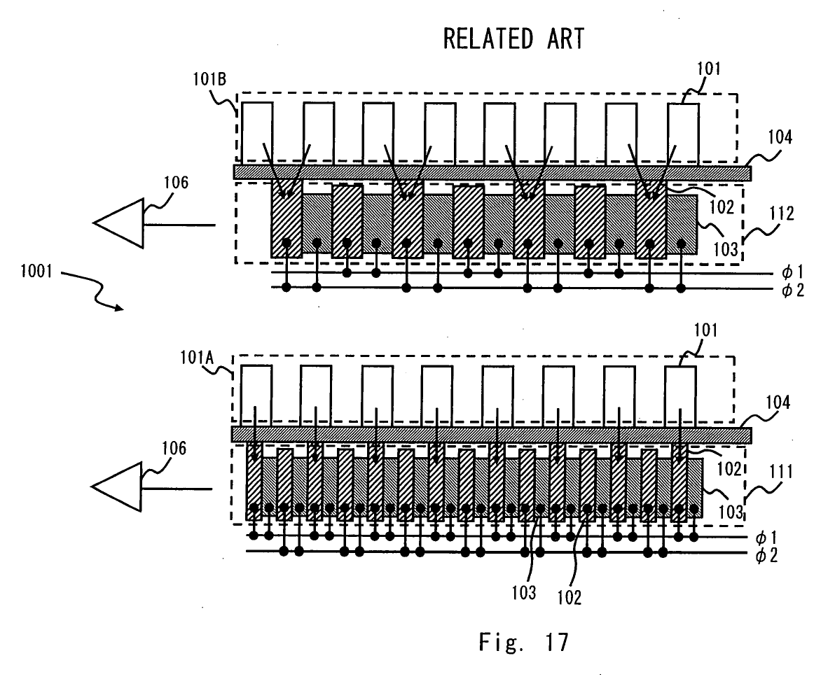

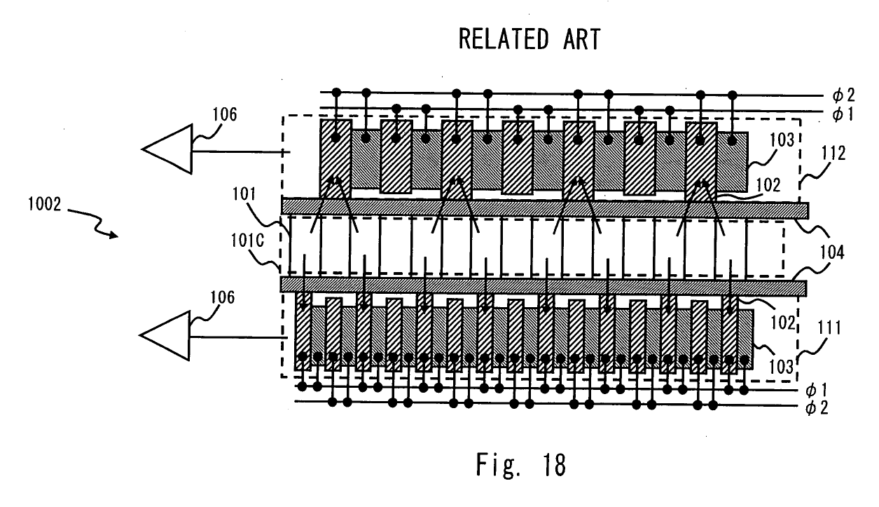

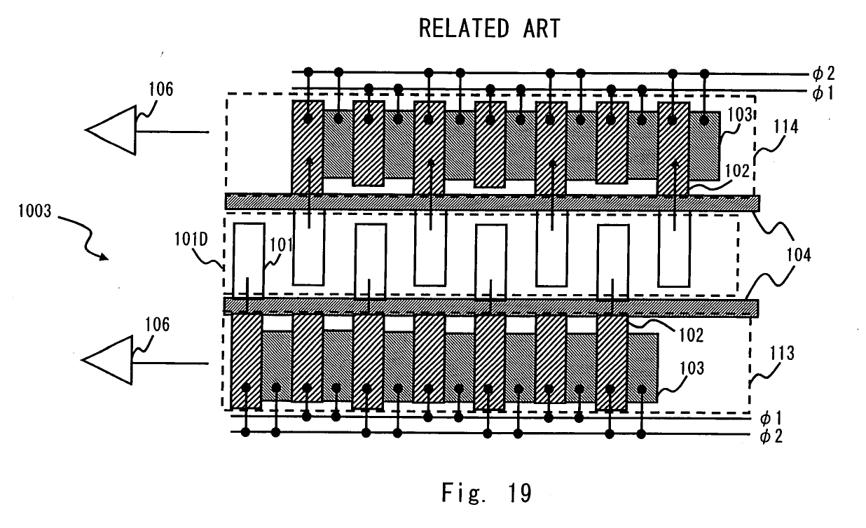

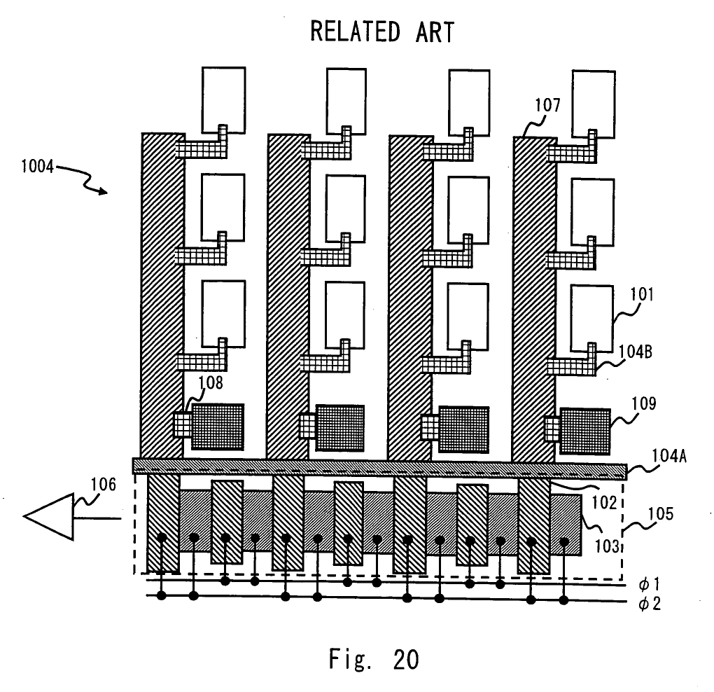

FIG. 15 is a schematic diagram of the section taken along the line Z1-Z1′ of FIG. 14 and a potential change. As shown in FIG. 15, if the reading gate is applied with a high-level voltage, and the signal φ1 is at High level, a potential is lowered in the order of the photodiode, the reading gate, and the accumulation gate. Accordingly, in such cases, charges generated by the photodiode are moved to the accumulation gate of the lowest potential. Further, if the signal φ1 is at Low level, the potential of the accumulation gate becomes higher (potential as indicated by the broken line of FIG. 15), so no charges are moved to the accumulation gate. Further, the shutter gate is supplied with the signal φ3. Hence, if the signal φ3 is at High level, a potential of the shutter gate is lowered, and charges generated by the photodiode are output to the reset drain. If the signal φ3 is at Low level, the potential of the shutter gate becomes higher, so no charges flow into the reset drain side.

In the CCD 600 of the sixth embodiment, if no charges are transferred to the accumulation gate with the signal φ1 , the shutter gate is controlled with the signal φ3, whereby charges generated by the photodiodes are output to the reset drain.

In the high-resolution mode, the CCD 600 of the sixth embodiment obtains pixel information through substantially the same operation as that of the fifth embodiment. Further, in the low-resolution mode, charges of one of adjacent photodiodes are used, and charges of the other photodiode are output using the rest drain. Hence, only the charges of one photodiode are transferred to the CCD unit, making it possible to prevent the CCD unit from being saturated with charges that flow into the unit.

Incidentally, the present invention is not limited to the above embodiments and can be variously modified. For example, there is no particular limitation on the layout as long as charges generated by plural photodiodes are transferred to the CCD accumulation gate of one main transfer element. Further, in each embodiment, the shutter gate or overflow drain may be provided adjacent to the photodiode for preventing the saturation with charges. Alternatively, the reset gate and the reset drain may be provided adjacent to the memory gate.

Further, it is possible to realize a color image sensor by providing different color filters for plural pixels corresponding to the CCD accumulation gate of one main transfer element.

Further, in the above embodiment, a two-phase drive clock pulse is used for driving the CCD unit, but the present invention is effective even with a three- or four-phase one. It is apparent that the present invention is not limited to the above embodiment that may be modified and changed without departing from the scope and spirit of the invention.

What is claimed is:

1. An image sensor, comprising:
a plurality of pixels arranged in line;
a reading gate adjacent to the plurality of pixels;
a plurality of memory gates formed adjacent to the reading gate and corresponding to the plurality of pixels;
a plurality of memory control gates corresponding to the memory gates; and
a CCD accumulation gate common to the plurality of memory control gates.

2. The image sensor according to claim 1, wherein the plurality of memory control gates are applied with the same control signal every integral number of memory control gates.

3. The image sensor according to claim 2, wherein the CCD accumulation gate is one of two CCD accumulation gates that constitute a two-phase drive charge transfer element.

4. The image sensor according to claim 3, further comprising:
a drain formed adjacent to the memory control gates and outputting the charges,
wherein the memory control gates are formed adjacent to the memory gates and control charges of the memory gates.

5. The image sensor according to claim 1, wherein the CCD accumulation gate is one of two CCD accumulation gates that constitute a two-phase drive charge transfer element.

6. The image sensor according to claim 5, further comprising:
a drain formed adjacent to the memory control gates and outputting the charges,
wherein the memory control gates are formed adjacent to the memory gates and control charges of the memory gates.

7. The image sensor according to claim 1, further comprising:
a drain formed adjacent to the memory control gates and outputting the charges,
wherein the memory control gates are formed adjacent to the memory gates and control charges of the memory gates.

8. The image sensor according to claim 1, further comprising:
a control circuit for controlling each of the plurality of memory control gates corresponding to the CCD accumulation gates, which supplies a control signal for collectively transferring charges from the plurality of memory control gates to the CCD accumulation gate in a first mode and supplies a control signal for separately transferring charges from the memory control gates to the CCD accumulation gate in a second mode.

9. The image sensor according to claim 7, wherein the control circuit applies to the charge transfer element including the CCD accumulation gate, a driving pulse for transferring charges after collectively transferring charges from the plurality of memory control gates to the CCD accumulation gate in the first mode, and a driving pulse for transferring charges after separately transferring charges from the plurality of memory control gates to the CCD accumulation gate in the second mode.

10. An image sensor, comprising:
a plurality of first pixels arranged in line;
a plurality of memory gates corresponding to the first pixels;
a first reading gate for transferring a signal charge from the first pixels to a corresponding one of the memory gates;
a plurality of second pixels corresponding to the plurality of memory gates and having a size different from the first pixels;
a second reading gate for transferring a signal charge from the second pixels to a corresponding one of the memory gates;
a charge transfer element formed adjacent to the memory gates; and
a third reading gate for transferring the signal charge transferred to the memory gates to the charge transfer element, which corresponds to each of the memory gates.

11. An image sensor, comprising:
a plurality of pixels arranged in line; and
a CCD unit including a plurality of CCD accumulation gates that are arranged in line, and accumulate and transfer charges transferred from the plurality of pixels,
wherein in a first mode, the charges transferred from the plurality of pixels are combined at the CCD accumulation gates and the CCD unit transfers the combined charges, and
in a second mode, the charges transferred from the plurality of pixels are individually transferred by the CCD unit.

12. The image sensor according to claim 10, further comprising:
a plurality of reading gates corresponding to the plurality of pixels; and
a control circuit for supplying a control signal to the reading gates,
wherein the CCD accumulation gate is provided common to the plurality of reading gates; and
the control circuit supplies a control signal for collectively transferring charges to the CCD accumulation gate from the plurality of reading gates in the first mode and supplies a control signal for separately transferring charges to the CCD accumulation gate from the plurality of reading gates in the second mode.

13. The image sensor according to claim 10, further comprising:
a reading gate formed adjacent to the plurality of pixels; and
a control circuit for applying a driving pulse to the CCD unit,
wherein the CCD accumulation gates correspond to the plurality of pixels in a one to one relation, and
the CCD unit transfers charges accumulated in one of adjacent CCD accumulation gates, to the other of the adjacent CCD accumulation gates, combines the charges of the adjacent CCD accumulation gates, and transfers the combined charges between the adjacent CCD accumulation gates, in response to the driving pulse from the control circuit in the first mode, and the CCD unit accumulates charges in one of the adjacent accumulation gates and transfers the accumulated charges between the adjacent accumulation gates, in response to the driving pulse from the control circuit in the second mode.
